(19) United States
(12) Patent Application Publication
(10) Pub. No.: US 2026/0362872 A1
(43) Pub. Date: Nov. 12, 2026

(54) APPARATUS, CARRIER, AND METHODS FOR MANUFACTURING A DISPLAY TILE

(71) Applicant: CORNING INCORPORATED, Corning, NY (US)

(72) Inventors: Richard Hagan, Corning, NY (US); Cody Daniel Hutcheson, Painted Post, NY (US)

(21) Appl. No.: 19/514,991

(22) PCT Filed: Aug. 6, 2024
(86) PCT No.: PCT/US2024/041026

§ 371 Date: Feb. 27, 2026

Related U.S. Application Data
(60) Provisional application No. 63/580,798, filed on Sep. 6, 2023.

(51) Int. Cl. H10H 29/01; H10P 72/00; H10P 72/76

(52) U.S. Cl. CPC H10H 29/0364; H10P 72/0448; H10P 72/7618

(57) ABSTRACT

An apparatus includes a carrier, an orifice, and a motion platform. The carrier is configured to secure a substrate. The orifice is configured to emit an aerosol jet. The motion platform is configured to, with the orifice emitting a continuous aerosol jet, move the carrier relative to the orifice to print a plurality of electrodes on a first major surface and an edge surface of the substrate.

### CROSS-REFERENCE TO RELATED APPLICATIONS

This application claims the benefit of priority under 35 U.S.C. § 119 of U.S. Provisional Application Serial No. 63/580798 filed on Sep. 6, 2023, the content of which is relied upon and incorporated herein by reference in its entirety.

### BACKGROUND

### Field

The present disclosure relates generally to methods and apparatus for manufacturing substrates with wrap-around electrodes. More particularly, it relates to methods and apparatus for manufacturing substrates with wrap-around electrodes using an aerosol jet.

### Technical Background

Displays, such as MicroLED displays, include borderless, bezel free, and/or tiled displays. Top emitting microLED displays require a method to electrically interconnect the LEDs on the substrate top surface with the driver controller board located behind the substrate. This may be accomplished by use of a flex connector attached at the substrate edge. In the case of a borderless, bezel free, or tiled display, however, it is not desirable to use a flex connector attached to the substrate top surface. In such case, the flex connector is either visible to the viewer and needs to be hidden by a bezel or the flex connector occupies too much space between tiles and prohibits seamless tiling. One solution for electrically connecting the display substrate top surface with the driver controller board is with wrap-around electrodes.

Wrap-around electrodes can be fabricated around substrate edges. This enables the electrodes to occupy less physical space and be less visibly observable. Wrap-around electrodes have been demonstrated with borderless, bezel free, and tiled displays. Such electrodes can comprise varying materials and be fabricated by methods including printing, vacuum deposition, flex connecting, and electroplating. Methods to improve wrap-around electrode electrical performance and reliability are being made through material and process improvements.

### SUMMARY

Some embodiments of the present disclosure relate to an apparatus for manufacturing a display tile. The apparatus includes a carrier, an orifice, and a motion platform. The carrier is configured to secure a substrate. The orifice is configured to emit an aerosol jet. The motion platform is configured to, with the orifice emitting a continuous aerosol jet, move the carrier relative to the orifice to print a plurality of electrodes on a first major surface and an edge surface of the substrate.

Yet other embodiments of the present disclosure relate to a carrier for manufacturing a display tile. The carrier includes a first carrier portion configured to contact a first major surface of a substrate. The first carrier portion includes a plurality of first magnets and a plurality of second magnets. The plurality of first magnets are configured to removably couple the first carrier portion to a motion platform of an apparatus for manufacturing the display tile. The plurality of second magnets are configured to secure the substrate to the first carrier portion.

Yet other embodiments of the present disclosure relate to a method for manufacturing a display tile. The method includes emitting a first continuous aerosol jet from an orifice. The method includes depositing, from the first continuous aerosol jet emitted from the orifice, a first portion of a first electrode on a first major surface and an edge surface of a substrate. The method includes depositing, from the first continuous aerosol jet emitted from the orifice, a first portion of a second electrode on the first major surface and the edge surface of the substrate.

The apparatus and methods disclosed herein enable high volume electrode printing (e.g., highly accurate, highly repetitive, and short stroke motion). The apparatus provides a zero friction print stroke, a greatly reduced friction index stroke, longer equipment life, increased accuracy (e.g., about +/−5 microns), and increased print speed compared to previous solutions.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary and are intended to provide an overview or framework to understanding the nature and character of the claims. The accompanying drawings are included to provide a further understanding and are incorporated in and constitute a part of this specification. The drawings illustrate one or more embodiment(s), and together with the description explain principles and operation of the various embodiments.

### BRIEF DESCRIPTION OF THE DRAWINGS

FIG. 1 is a perspective view of an exemplary substrate;

FIG. 2 is a perspective view of electrode deposition on a substrate positioned at an angled orientation relative to a deposition orifice;

FIG. 3 is a side cutaway view of a portion of a substrate with a wrap-around electrode deposited thereon;

FIG. 4 is a perspective view of an exemplary apparatus for printing a plurality of wrap-around electrodes on a substrate;

FIG. 5 is a perspective view of an exemplary carrier of the apparatus of FIG. 4;

FIG. 6 is a perspective view of an exemplary carrier portion of the carrier of FIG. 5;

FIG. 7A is a perspective view and FIG. 7B is a partial side view of an exemplary carrier and an exemplary alignment fixture for positioning a substrate within the carrier;

FIG. 8 is a perspective view of another exemplary carrier and another exemplary alignment fixture for positioning a substrate within the carrier;

FIG. 9 is a partial cross-sectional view of an exemplary carrier portion coupled to a motion platform;

FIG. 10 is a partial side view of the apparatus of FIG. 4;

FIG. 11 is a side cutaway view of the apparatus of FIG. 4; and

FIGS. 12A-12D are flow diagrams of an exemplary method for manufacturing a display tile.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. However, this disclosure may be embodied in many different forms and should not be construed as limited to the embodiments set forth herein.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein-for example up, down, right, left, front, back, top, bottom, vertical, horizontal-are made only with reference to the figures as drawn and are not intended to imply absolute orientation.

Unless otherwise expressly stated, it is in no way intended that any method set forth herein be construed as requiring that its steps be performed in a specific order, nor that with any apparatus, specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an,” and “the” include plural references unless the context clearly dictates otherwise. Thus, for example, reference to “a” component includes aspects having two or more such components, unless the context clearly indicates otherwise.

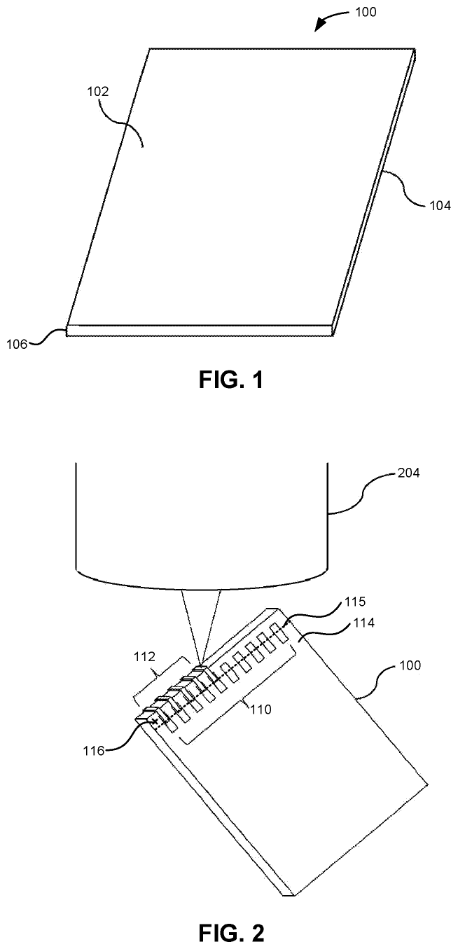

Referring now to FIG. 1, a perspective view of an exemplary substrate 100 is depicted. Substrate 100 includes a first major surface 102, an opposing second major surface 104 extending in a generally parallel direction to the first major surface 102 (on the opposite side of the substrate 100 as the first major surface) and an edge surface 106 extending between the first major surface 102 and the second major surface 104 and extending in a generally perpendicular direction to the first major surface 102 and the second major surface 104.

In certain exemplary embodiments, substrate 100 may include a glass substrate including a glass material, such as aluminosilicate, alkali-aluminosilicate, borosilicate, alkali-borosilicate, aluminoborosilicate, alkali-aluminoborosilicate, soda lime, or other suitable glasses. Non-limiting examples of commercially available glasses suitable for use as a glass substrate 100 include EAGLE XG®, Lotus™, Willow®, Iris™, and Gorilla® glasses from Corning Incorporated. The substrate 100 may have a thickness between the first major surface 102 and the second major surface 104 within a range, for example, from about 0.1 millimeters to about 2 millimeters. The substrate 100 may have a refractive index within a range, for example, between about 1.5 and 2.4.

FIG. 2 is a perspective view of electrode deposition on a substrate 100 positioned at an angled orientation relative to a deposition orifice 204. As shown in FIG. 2, a plurality of contact pads 110 are arranged on a major surface of the substrate 100 and at least a portion of a plurality of electrodes 112 are deposited onto the contact pads 110, the major surface, and an edge surface of the substrate 100. The substrate 100 may then be rotated or turned over to allow deposition of at least a portion of the plurality of electrodes 112 onto the opposing major surface and the edge surface of the substrate 100. In certain exemplary embodiments, a mask 114 including an edge 115 indicated by the dotted line may be applied over a portion of the major surface to prevent deposition on the major surface where deposition is not desired. In addition, the substrate 100 may include a fiducial 116, which may be used for initially positioning the substrate 100 relative to the orifice 204 prior to depositing the electrodes 112. Electrode deposition wherein a substrate can be oriented at a variety of angles relative to a deposition orifice is, for example, disclosed in WO2019079253, the entire disclosure of which is incorporated herein by reference. Deposition of such electrodes may be by a variety of technologies including, but not limited to, printed seed layer plating, direct printing, laser induced metallization, pen dispensing, and aerosol jetting.

Embodiments disclosed herein include those in which electrodes are deposited on a substrate via an aerosol jet. Aerosol jet deposition is described, for example, in US20090061077, the entire disclosure of which is incorporated herein by reference. Such deposition includes using an aerosol jet to form an annularly propagating jet comprising an outer sheath flow and an inner aerosol-laden carrier flow. In the aerosol jetting process, the aerosol stream enters a print head, preferably either directly after the aerosolization process or after passing through a heater assembly and is directed along the axis of the device towards a print head orifice. The mass throughput can be controlled by an aerosol carrier gas mass flow controller. Inside the print head, the aerosol stream can be collimated by passing through an about 0.1 millimeter-size orifice. The emergent particle stream can then be combined with an annular sheath gas, which functions to eliminate clogging of the nozzle and to focus the aerosol stream. The carrier gas and the sheath gas may, for example, comprise dry nitrogen, compressed air, or an inert gas, where one or all may be modified to contain solvent vapor. For example, when the aerosol is formed from an aqueous solution, water vapor may be added to the carrier gas or the sheath gas to prevent droplet evaporation.

The sheath gas may then enter through a sheath air inlet below the aerosol inlet and form an annular flow with the aerosol stream. As with the aerosol carrier gas, the sheath gas flowrate may be controlled by a mass flow controller. The combined streams exit the nozzle at a high velocity (e.g., about 50 meters per second) through an orifice directed at a target and subsequently impinge upon the target. This annular flow focuses the aerosol stream onto the target and allows for printing of features with dimensions smaller than, for example, about 1 micron. Printed patterns may be created by moving the target relative to the print head and/or the print head relative to the target. Examples of commercially available aerosol jet print heads, devices, and systems include those available from Optomec Incorporated.

Electrical traces (e.g., electrodes) may be formed to extend from the first major surface 102 of the substrate 100 to the second major surface 104 of the substrate opposite to the first major surface using a multistep process that includes multiple passes of non-contact aerosol jetting using an electrically conductive nanoparticle ink. The nanoparticle ink may be atomized utilizing a venturi atomization process and a carrier gas as described above. The gas may then be focused into a small deposition stream and deposited onto one side of the substrate 100. The focus height from the orifice 204 may be large enough such that when the substrate 100 is held at a specified angle, the orifice 204 can print on the top surface and the edge surface of the substrate 100. Once the nanoparticle ink is dry, the substrate 100 may be flipped over and printing may continue on the other side of the substrate to join or create the electrical traces (e.g., electrodes) wrapped around the edge of the substrate between the first major surface 102 and the second major surface 104. The completed part may then undergo a thermal cycle to bond the nanoparticle ink to the surfaces of the substrate 100.

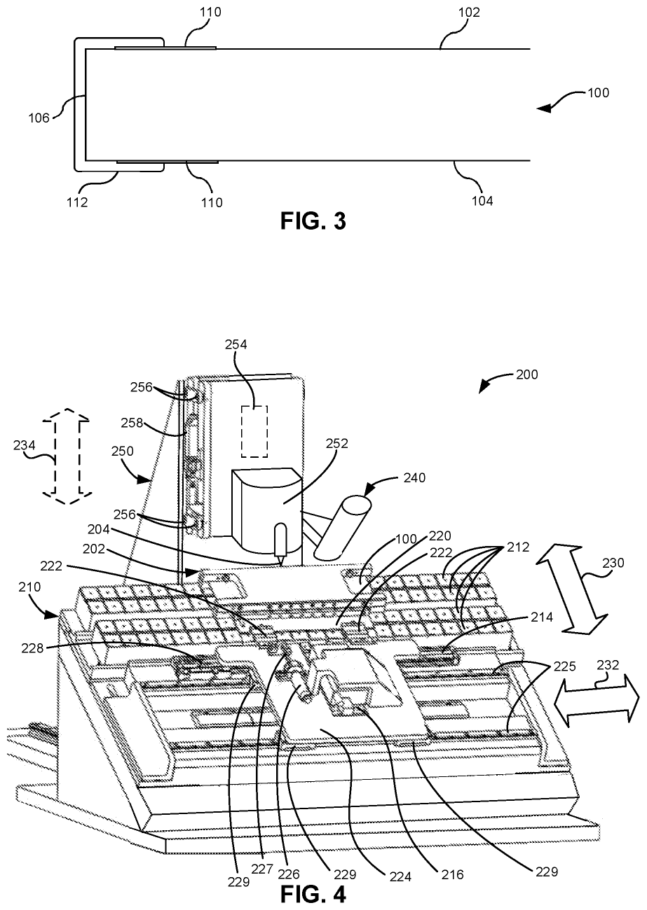

FIG. 3 is a side cutaway view of a portion of a substrate 100 with a wrap-around electrode 112 deposited thereon. Specifically, the electrode 112 extends along a portion of first major surface 102, the edge surface 106, and the second major surface 104 of the substrate 100 while contacting the contact pads 110. While the edge region of the substrate 100 is shown as having a rectangular cross-section, embodiments disclosed herein include those in which the edge region of the substrate 100 has other cross sections, including but not limited to those including curved or angled (e.g., chamfered) regions (not shown). Electrode 112 may comprise an electrically conductive material, such as an electrically conductive metallic material, including, for example, at least one material selected from silver or copper.

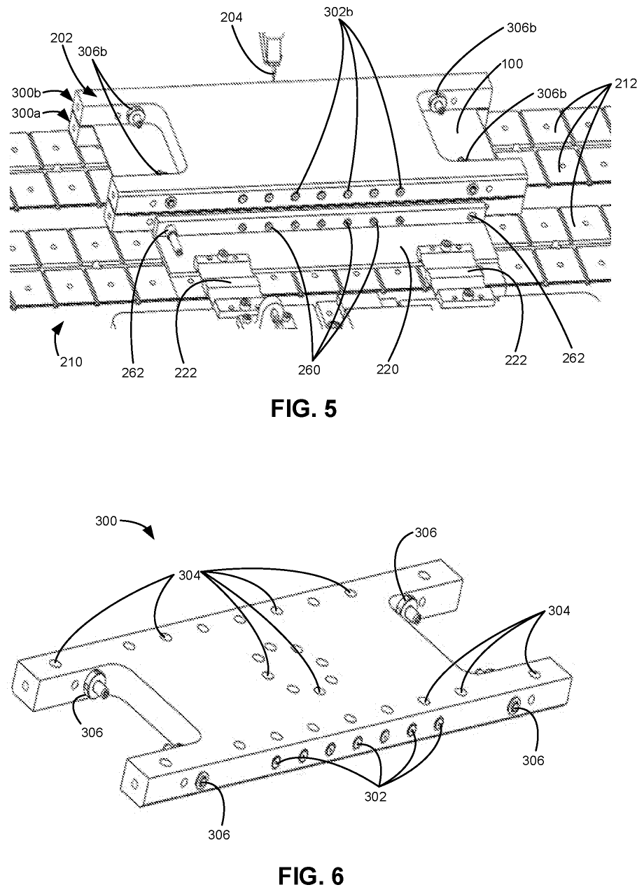

FIG. 4 is a perspective view of an exemplary apparatus 200 for printing a plurality of wrap-around electrodes (e.g., 112 of FIG. 3) on a substrate 100. In certain exemplary embodiments, the apparatus 200 may be used to manufacture display tiles. The apparatus 200 includes a carrier 202, a print head 252 including an orifice 204, and a motion platform 210. The carrier 202 is configured to secure the substrate 100 as described in more detail below with reference to FIGS. 5-8. The orifice 204 is configured to emit an aerosol jet to deposit electrical traces (e.g., electrodes) on the substrate 100. The motion platform 210 is configured to move the carrier 202 relative to the orifice 204. In some embodiments, the motion platform 210 is configured to, with the orifice 204 emitting a continuous aerosol jet, move the carrier 202 relative to the orifice 204 to print a plurality of electrodes on a first major surface 102 (FIG. 3) and an edge surface 106 (FIG. 3) of the substrate 100. In some embodiments, the motion platform 210 is configured to, with the carrier 202 flipped over and with the orifice 204 emitting a continuous aerosol jet, move the carrier 202 relative to the orifice 204 to print a plurality of electrodes on a second major surface 104 (FIG. 3) and an edge surface 106 of the substrate 100.

In the exemplary apparatus 200 illustrated in FIG. 4, the motion platform 210 may include a plurality of air bearings 212; a first non-contact linear motor 214; a second non-contact linear motor 216; a third non-contact linear motor 254 (hidden behind a plate and not visible in FIG. 4); a plurality of flexures 220, 222, 224, and 256; a plurality of encoders 226, 228, and 258, a print head tower 250; and an optical system 240. The carrier 202 floats on the plurality of air bearings 212. In certain exemplary embodiments, the plurality of air bearings 212 include vacuum preloaded air bearings to provide stiff and flat bearings to allow frictionless conveyance between the bearings and the carrier 202. The carrier 202 is removably coupled to the flexure 220 of the motion platform 210. The flexure 220, which also floats on the plurality of air bearings 212, is coupled to the flexure 224 via two decoupling flexures 222. The flexures 220, 222, and 224 couple the carrier 202 to the first non-contact linear motor 214 and the second non-contact linear motor 216.

The first non-contact linear motor 214 moves the carrier 202 relative to the orifice 204 along an index stroke axis 232 (e.g., a first axis). The second non-contact linear motor 216 moves the carrier 202 relative to the orifice 204 along a print stroke axis 230 (e.g., a second axis) perpendicular to the index stroke axis 232. In certain exemplary embodiments, the orifice 204 is stationary while printing the plurality of electrodes (e.g., 112) on the substrate 100. In some embodiments, the print head tower 250 is configured to position the orifice 204 relative to the substrate 100. The third non-contact linear motor 254 may be used to incorporate a small vertical print head stroke, along a nozzle motion axis 234 parallel to the aerosol jet emitted from the orifice 204, into the printing process to maintain an offset between the orifice 204 and the substrate 100 as the aerosol jet wraps the edge of the substrate 100. By using a small vertical print head stroke, electrical trace uniformity may be further improved. The print head tower 250 includes the flexures 256 (e.g., rotational flexures configured to provide parallel motion) coupling the print head 252 and the orifice 204 to the non-contact linear motor 254 to enable the vertical print head stroke.

In certain exemplary embodiments, the non-contact linear motors 214, 216, and 254 are frictionless and coupled with air bearings support and the flexures described herein to provide zero friction motion along the print stroke axis 230 and the nozzle motion axis 234 as well as extremely low friction motion along the index stroke axis 232. In certain exemplary embodiments, each non-contact linear motor 214, 216, and 254 includes a coil and magnetic tracks where the coil rides on the magnetic tracks. Encoder 226 may be used to provide feedback to control the position of the substrate 100 relative to the orifice 204 along the print stroke axis 230. Encoder 228 may be used to provide feedback to control the position of the substrate 100 relative to the orifice 204 along the index stroke axis 232. Encoder 258 may be used to provide feedback to control the position of the orifice 204 relative to the substrate 100 along the nozzle motion axis 234.

The flexure 220 (e.g., a rotational flexure configured to provide parallel motion) used to connect the carrier 202 to the motion platform 210 limits flatness errors of the substrate 100 and/or the carrier 202 that could be induced by the motion platform 210. The flexures 222 (e.g., rotational flexures configured to provide parallel motion) are decoupling flexures coupling the flexure 220 to the flexure 224. The flexure 224 (e.g., a rotational flexure configured to provide parallel motion) is a flexure plate for print stroke bearing. The flexure 224 rides on linear rails 225 along the index stroke axis 232 via ball bearing carriages 229. The flexure 224 provides a repeatable frictionless bearing with a theoretically infinite life. The flexure 224 provides an increased longevity compared to a traditional contact bearing given the highly repetitive, and short stroke nature of the motion used to print wrap-around electrodes. The flexures 256 accommodate the short and repetitive strokes of vertical motion of the print head 252. The flexures 256 provide a repeatable frictionless bearing with increased longevity compared to a traditional bearing. Additional flexures, such as an encoder flexure 227 for encoder 226, may be used to limit any non-axial forces transferred to the encoders 226, 228, and 258. The encoder flexures may also serve as a weak link in the event of a motion crash and/or malfunction.

The optical system 240 is configured to calibrate the orifice location 204 each time the orifice 204 as part of the print head 252 is changed. The optical system 240 is also configured to position the substrate 100 (e.g., by moving the carrier 202 securing the substrate 100) relative to the orifice 204 based on a fiducial 116 (FIG. 2) on the substrate 100 prior to printing the plurality of electrodes (e.g., 112). The optical system 240 is further described below with reference to FIG. 10.

In operation, the carrier 202 may be moved into and out of a continuous aerosol jet emitted from the orifice 204 to print a plurality of electrical traces (e.g., electrodes) on a major surface and an edge surface of the substrate 100. The print head 252 is turned on at the beginning of the print and remains on for the duration of the print. The substrate 100 is indexed to the next electrical trace when the substrate is out of the aerosol jet path thus eliminating the need for ink shuttering. In this way, run time and ink flow uniformity is maximized. In addition, motion errors associated with the print head 252 due to its cantilevered mounting design are eliminated.

The substrate 100 starting position is out of the aerosol jet path and the substrate is indexed to the proper starting location (e.g., based on fiducial 116). Each of the printed electrical traces is the result of two print strokes (one driving the substrate into the aerosol jet path and another pulling the substrate back out of the aerosol jet path without a move in the index direction). Due to this print strategy, rapid acceleration control is used to accelerate the substrate to the correct print speed, control the print speed, decelerate to zero as quickly as possible because the substrate is still under the aerosol jet path, accelerate back up to print speed in the opposite direction, and control the print speed as the substrate leaves the aerosol jet path, and then decelerate back to zero during the next index move. Apparatus 200 is designed to minimize the moving mass, thus increasing the ability to accelerate and decelerate rapidly.

In some embodiments, a mask (e.g., 114 of FIG. 2) may be applied over the substrate 100 that allows the substrate to be moved in the aerosol jet path while preventing ink from being deposited on the substrate where the ink is not intended and/or needed. By using a mask, print times may be further reduced by eliminating the double print stroke for each electrical trace.

FIG. 5 is a perspective enlarged view of an exemplary carrier 202 coupled to a motion platform 210 of the apparatus 200 of FIG. 4. As shown in FIG. 5, the motion platform 210 includes a plurality of magnets 260 (as part of flexure 220) to removably couple the carrier 202 to the motion platform. In addition, the motion platform 210 includes a plurality of vees 262 configured to receive kinematic ball end adjusters of a carrier 202 (e.g., 306 of FIG. 6) to position the carrier 202 relative to the flexure 220 as will be further described below.

The carrier 202 may include a first carrier portion 300a and a second carrier portion 300b. In certain exemplary embodiments, the first carrier portion 300a and the second carrier portion 300b are identical as indicated by carrier portion 300 illustrated in FIG. 6. The first carrier portion 300a and the second carrier portion 300b are symmetric so that once the substrate 100 is secured within the carrier 202, the carrier can be rotated and flipped to enable printing on the top and bottom sides of both long edges of the substrate. In other examples, as further described below with reference to FIG. 8, the carrier 202 may include a single carrier portion 300 and a plurality of magnets to secure the substrate 100 to the single carrier portion 300.

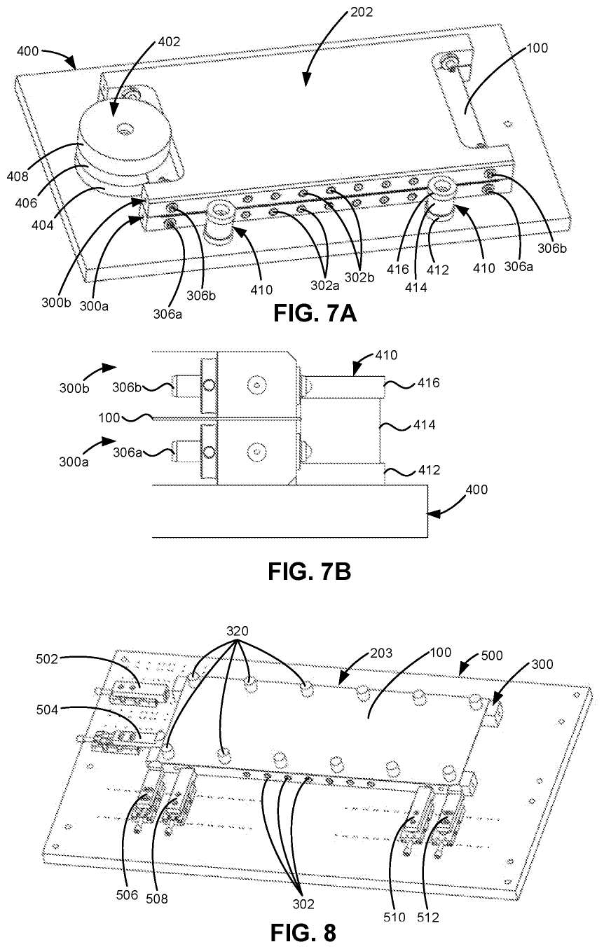

Referring back to FIGS. 5 and 6, the first carrier portion 300a is configured to contact a first major surface (e.g., 102 of FIG. 1) of the substrate 100. The first carrier portion 300a includes a plurality of first magnets 302a (not visible in FIG. 5 but shown in FIG. 7A) and a plurality of second magnets 304 (not visible in FIG. 5 but shown in FIG. 6). The plurality of first magnets 302a of the first carrier portion 300a are configured to removably couple the first carrier portion 300a to the motion platform 210 via the flexure 220. The first carrier portion 300a is removably coupled to the flexure 220 by positioning the first plurality of magnets 302a opposite to the corresponding plurality of magnets 260 of the flexure 220. The plurality of kinematic adjusters 306a (not visible in FIG. 5 but shown in FIG. 7A) of the first carrier portion 300a are configured to adjust the position of the first carrier portion 300a relative to the motion platform 210 (e.g., relative to the flexure 220) by engaging vees 262.

The second carrier portion 300b is configured to contact the second major surface (e.g., 104 of FIG. 1) of the substrate 100 opposite to the first major surface of the substrate 100. The second carrier portion 300b includes a plurality of third magnets 304 (not visible in FIG. 5 but shown in FIG. 6) opposite to the plurality of second magnets 304 of the first carrier portion 300a to secure the substrate 100 between the first carrier portion 300a and the second carrier portion 300b. The second carrier portion 300b also includes a plurality of fourth magnets 302b configured to removably couple the second carrier portion to the motion platform 210 via the flexure 220 when the carrier 202 is flipped over to print the electrodes on the second major surface and the edge surface of the substrate 100.

FIG. 7A is a perspective view and FIG. 7B is a partial side view of an exemplary carrier 202 and an exemplary alignment fixture 400 for repeatably positioning a substrate 100 within the carrier 202. In some examples, a first polyimide film interposer layer may be added between the first carrier portion 300a and the first major surface of the substrate, and a second polyimide film interposer layer may be added between the second carrier portion 300b and the second major surface of the substrate to protect the substrate. The alignment fixture 400 includes a precisely machined dowel 402 and two precisely machined dowels 410. In certain exemplary embodiments, dowels 402 and 410 are polyetheretherketone (PEEK) dowels.

Dowel 402 includes a first portion 404 configured to contact the first carrier portion 300a (e.g., within a recess of a short side of the first carrier portion 300a), a second portion 406 configured to contact the substrate 100, and a third portion 408 configured to contact the second carrier portion 300b (e.g., within a recess of a short side of the second carrier portion 300b). The first portion 404 and the third portion 408 have the same radius such that the side surface of the first carrier portion 300a is aligned with the side surface of the second carrier portion 300b. The second portion 406 has a radius less than the radius of the first portion 404 and the third portion 408 such that the substrate 100 extends into the recess on the side surface of each of the first carrier portion 300a and the second carrier portion 300b. Dowel 402 sets the offset between the short edge of the substrate 100 and each short side surface of the first carrier portion 300a and the second carrier portion 300b. Different dowels 402 including different radiuses for the first portion 404, the second portion 406, and the third portion 408 may be used to support different offsets between the carrier 202 and the substrate 100.

As best illustrated in FIG. 7B, each dowel 410 includes a first portion 412 configured to contact the first carrier portion 300a (e.g., on a long side of the first carrier portion 300a), a second portion 414 configured to contact the substrate 100, and a third portion 416 configured to contact the second carrier portion 300b (e.g., on a long side of the second carrier portion 300b). The first portion 412 and the third portion 416 have the same radius such that the side surface of the first carrier portion 300a is aligned with the side surface of the second carrier portion 300b. The second portion 414 has a radius less than the radius of the first portion 412 and the third portion 416 such that the substrate 100 extends beyond the side of each of the first carrier portion 300a and the second carrier portion 300b. Each dowel 410 sets the offset between the long edge of the substrate 100 and each long side surface of the first carrier portion 300a and the second carrier portion 300b. Different dowels 410 including different radiuses for the first portion 412, the second portion 414, and the third portion 416 may be used to support different offsets between the carrier 202 and the substrate 100.

FIG. 8 is a perspective view of another exemplary carrier 203 and another exemplary alignment fixture 500 for repeatably positioning a substrate 100 within the carrier 203. The carrier 203 includes a carrier portion 300 as previously described and illustrated with reference to FIG. 6 and a plurality of third magnets 320 (e.g., coated magnets to prevent damage to the substrate 100). Each third magnet 320 is configured to be arranged on a second major surface of the substrate 100 opposite to the first major surface and opposite to a corresponding second magnet 304 (FIG. 6) embedded in the carrier portion 300 to secure the substrate 100 to the carrier portion 300. In some examples, a polyimide film interposer layer may be added between the carrier portion 300 and the major surface of the substrate to protect the substrate. The carrier 203 may be used in place of the carrier 202 when electrodes are printed on one major surface and the edge surface of the substrate 100 but not on the other major surface of the substrate.

The alignment fixture 500 includes independently adjustable stops 502, 504, 506, 508, 510, and 512 to align the substrate 100 with the carrier portion 300. Independently adjustable stop 502 is configured to contact a short side surface of the carrier portion 300, while independently adjustable stop 504 is configured to contact a short edge of the substrate 100 to align the short edge of the substrate relative to the short side surface of the carrier portion 300. Independently adjustable stops 508 and 510 are configured to contact a long side surface of the carrier portion 300, while independently adjustable stops 506 and 512 are configured to contact a long edge of the substrate 100 to align the long edge of the substrate relative to the long side surface of the carrier portion 300.

Independently adjustable stops 502, 508, and 510 may include kinematic flat and vee components that interface with the kinematic adjusters 306 (FIG. 6) on the carrier portion 300. Independently adjustable stops 504, 506, and 512 may be machined PEEK stops to set the location of the substrate 100 and reduce the likelihood of damage to the substrate 100. This embodiment could be adapted to incorporate a vacuum to hold the substrate 100 to the carrier portion 300. In that case, the alignment fixture 500 and substrate/carrier configuration could be used to print electrodes that wrap on to both major surfaces of the substrate.

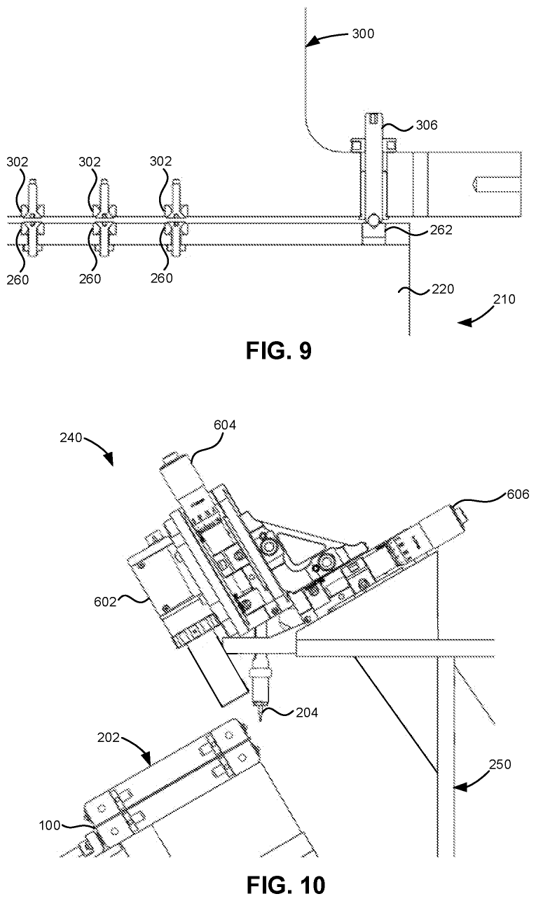

FIG. 9 is a partial cross-sectional view of an exemplary carrier portion 300 coupled to the motion platform 210. The magnets 302 of the carrier portion 300 correspond to the magnets 260 of the flexure 220 of the motion platform 210 to removably couple the carrier portion 300 to the motion platform 210. Kinematic ball end adjuster 306 of carrier portion 300 engages vee 262 of the flexure 220. The kinematic ball end adjuster 306 may be adjusted to alter the position of the carrier portion 300 relative to the flexure 220 of the motion platform 210.

FIG. 10 is a partial side view of the apparatus 200 of FIG. 4 illustrating the optical system 240 and the carrier 202. The optical system 240 includes a camera 602, a first adjustment mechanism 604, and a second adjustment mechanism 606. The optical system 240 is mounted to the print head tower 250 such that the camera 602 is perpendicular to a major surface of the substrate 100 to provide optimum image quality. The first adjustment mechanism 604 (e.g., a micrometer adjuster) may be adjusted to calibrate the position of the camera 602 along the camera axis (e.g., the axis perpendicular to a major surface of the substrate 100) relative to the substrate 100. The second adjustment mechanism 606 (e.g., a micrometer adjuster) may be adjusted to calibrate the position of the camera 602 along the axis perpendicular to the camera axis (e.g., the axis parallel to a major surface of the substrate 100) relative to the substrate 100.

The optical system 240 is used to calibrate the print head 252 (FIG. 4) location and thus orifice 204 location each time the print head is changed. In certain exemplary embodiments, the calibration routine includes printing a fiducial (e.g., 116 of FIG. 2) on the substrate 100 and then moving the printed fiducial under the camera 602 and using the camera to precisely locate the center of the fiducial within the field of view. Once the center of the fiducial is found, the location within the field of view in pixels can be converted into machine coordinates and microns to accurately indicate the location the aerosol jet impacts the substrate 100. The optical system 240 may also be used to locate substrates 100 on which electrodes are to be printed by referencing existing fiducial locations on the substrates. In certain exemplary embodiments, the calibration and alignment processes using the optical system 240 results in print accuracies greater than about +/−5 microns.

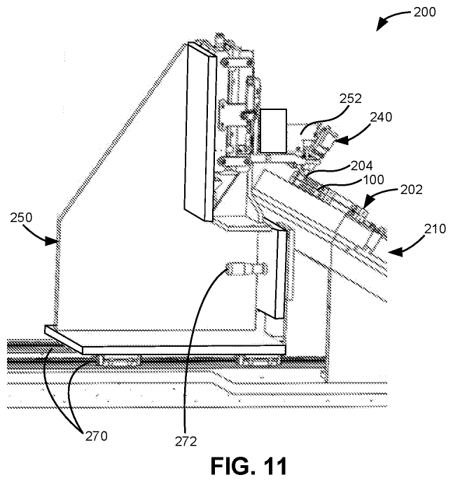

FIG. 11 is a side cutaway view of the apparatus 200 of FIG. 4 illustrating the motion platform 210 including the print head tower 250. The print head tower 250 may ride on linear rails 270 to enable the orifice 204 to be positioned relative to the substrate 100 along an axis perpendicular to the aerosol jet. The print head tower 250 may include an adjustment mechanism 272 (e.g., a micrometer adjuster) that may be adjusted to precisely optimize the print head 252 location and thus the orifice 204 location relative to the substrate 100 upon initial setup of the apparatus 200.

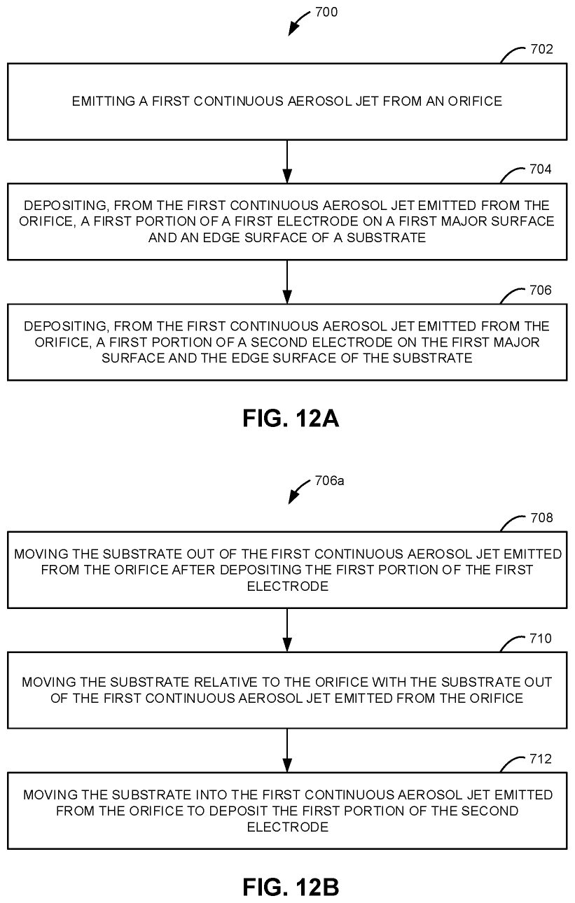

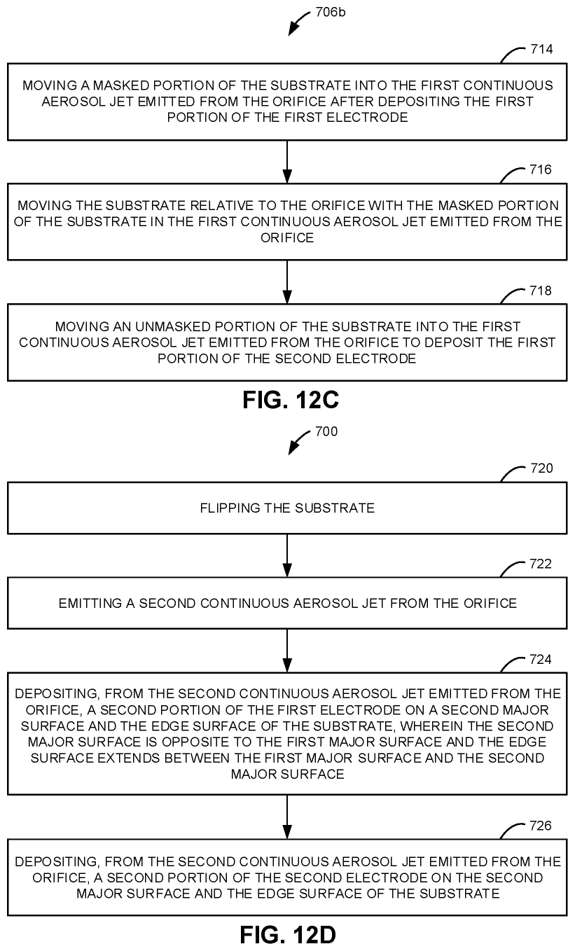

FIGS. 12A-12D are flow diagrams of an exemplary method 700 for manufacturing a display tile. In certain exemplary embodiments, method 700 may be implemented by apparatus 200 previously described and illustrated with reference to FIGS. 4-11. Method 700 may be used to print wrap-around electrodes 112 on a substrate 100 as illustrated in FIG. 3. As illustrated in FIG. 12A at 702, method 700 may include emitting a first continuous aerosol jet from an orifice (e.g., 204). At 704, method 700 may include depositing, from the first continuous aerosol jet emitted from the orifice, a first portion of a first electrode (e.g., a first electrode 112) on a first major surface (e.g., 102) and an edge surface (e.g., 106) of a substrate (e.g., 100). At 706, method 700 may include depositing, from the first continuous aerosol jet emitted from the orifice, a first portion of a second electrode (e.g., a second electrode 112 adjacent to the first electrode 112) on the first major surface and the edge surface of the substrate.

In some embodiments, as illustrated in FIG. 12B, step 706 of method 700 of FIG. 12A may further include method 706a. At 708, method 706a may include moving the substrate out of the first continuous aerosol jet emitted from the orifice after depositing the first portion of the first electrode (e.g., by moving, via the non-contact linear motor 216, the carrier 202 along the print stroke axis 230 away from the orifice 204). At 710, method 706a may include moving the substrate relative to the orifice with the substrate out of the first continuous aerosol jet emitted from the orifice (e.g., by moving, via the non-contact linear motor 214, the carrier 202 along the index stroke axis 232 parallel to the carrier 202). At 712, method 706a may include moving the substrate into the first continuous aerosol jet emitted from the orifice to deposit the first portion of the second electrode (e.g., by moving, via the non-contact linear motor 216, the carrier 202 along the print stroke axis 230 toward the orifice 204). In this embodiment, a double print stroke is used to print each electrode, one print stroke from the edge of the substrate toward the center of the substrate and one print stroke back to the edge of the substrate.

In some embodiments, as illustrated in FIG. 12C, step 706 of method 700 of FIG. 12A may further include method 706b. At 714, method 706b may include moving a masked portion (e.g., 114) of the substrate (e.g., 100) into the first continuous aerosol jet emitted from the orifice after depositing the first portion of the first electrode (e.g., by moving, via the non-contact linear motor 216, the carrier 202 along the print stroke axis 230 toward the orifice 204 such that the aerosol jet impacts the masked portion 114 of the substrate 100). At 716, method 706b may include moving the substrate relative to the orifice with the masked portion of the substrate in the first continuous aerosol jet emitted from the orifice (e.g., by moving, via the non-contact linear motor 214, the carrier 202 along the index stroke axis 232 parallel to the carrier 202). At 718, method 706b may include moving an unmasked portion of the substrate into the first continuous aerosol jet emitted from the orifice to deposit the first portion of the second electrode (e.g., by moving, via the non-contact linear motor 216, the carrier 202 along the print stroke axis 230 away from the orifice 204). In this embodiment, the mask on the substrate enables the substrate to be moved while in the path of the aerosol jet and prevent printing on the substrate where not intended and/or needed. By using a mask on the substrate, print times may be reduced by eliminating the double print stroke for each electrode.

As illustrated in FIG. 12D at 720, method 700 may further include flipping the substrate (e.g., by removing the carrier 202 from the motion platform 210, turning over the carrier 202, and recoupling the carrier 202 to the motion platform 210). At 722, method 700 may further include emitting a second continuous aerosol jet from the orifice. At 724, method 700 may further include depositing, from the second continuous aerosol jet emitted from the orifice, a second portion of the first electrode on a second major surface (e.g., 104) and the edge surface (e.g., 106) of the substrate (e.g., 100), wherein the second major surface is opposite to the first major surface (e.g., 102) and the edge surface extends between the first major surface and the second major surface. At 726, method 700 may further include depositing, from the second continuous aerosol jet emitted from the orifice, a second portion of the second electrode on the second major surface and the edge surface of the substrate.

It will be apparent to those skilled in the art that various modifications and variations can be made to embodiments of the present disclosure without departing from the spirit and scope of the disclosure. Thus, it is intended that the present disclosure cover such modifications and variations provided they come within the scope of the appended claims and their equivalents.

What is claimed is:

1. An apparatus for manufacturing a display tile comprising:
a carrier configured to secure a substrate;
an orifice configured to emit an aerosol jet; and
a motion platform configured to, with the orifice emitting a continuous aerosol jet, move the carrier relative to the orifice to print a plurality of electrodes on a first major surface and an edge surface of the substrate.

2. The apparatus of claim 1, wherein the motion platform comprises a plurality of air bearings on which the carrier floats.

3. The apparatus of claim 1, wherein the motion platform comprises a non-contact linear motor to move the carrier relative to the orifice.

4. The apparatus of claim 3, wherein the motion platform comprises a flexure coupling the carrier to the non-contact linear motor.

5. The apparatus of claim 1, wherein the motion platform comprises a plurality of magnets to removably couple the carrier to the motion platform.

6. The apparatus of claim 1, wherein the motion platform is configured to move the carrier along a first axis and a second axis perpendicular to the first axis.

7. The apparatus of claim 1, further comprising:
an optical system configured to calibrate the orifice location each time the orifice is changed.

8. The apparatus of claim 7, wherein the optical system is further configured to position the substrate relative to the orifice based on a fiducial on the substrate prior to printing the plurality of electrodes.

9. The apparatus of claim 1, wherein the orifice is stationary while printing the plurality of electrodes.

10. The apparatus of claim 1, further comprising:
a print head tower configured to position the orifice relative to the substrate.

11. The apparatus of claim 10, wherein the print head tower comprises a non-contact linear motor to move the orifice relative to the substrate.

12. The apparatus of claim 11, wherein the print head tower comprises a flexure coupling the orifice to the non-contact linear motor.

13. A carrier for manufacturing a display tile, the carrier comprising:
a first carrier portion configured to contact a first major surface of a substrate, the first carrier portion comprising:
a plurality of first magnets configured to removably couple the first carrier portion to a motion platform of an apparatus for manufacturing the display tile; and
a plurality of second magnets configured to secure the substrate to the first carrier portion.

14. The carrier of claim 13, wherein the first carrier portion further comprises a plurality of first kinematic adjusters configured to adjust a position of the first carrier portion relative to the motion platform.

15. The carrier of claim 13, further comprising:
a plurality of third magnets, each third magnet configured to be arranged on a second major surface of the substrate opposite to the first major surface and opposite to a corresponding second magnet of the plurality of second magnets to secure the substrate to the first carrier portion.

16. The carrier of claim 13, further comprising:
a second carrier portion configured to contact a second major surface of the substrate opposite to the first major surface, the second carrier portion comprising:
a plurality of third magnets opposite to the plurality of second magnets to secure the substrate between the first carrier portion and the second carrier portion; and
a plurality of fourth magnets configured to removably couple the second carrier portion to the motion platform.

17. A method for manufacturing a display tile, the method comprising:
emitting a first continuous aerosol jet from an orifice;
depositing, from the first continuous aerosol jet emitted from the orifice, a first portion of a first electrode on a first major surface and an edge surface of a substrate; and
depositing, from the first continuous aerosol jet emitted from the orifice, a first portion of a second electrode on the first major surface and the edge surface of the substrate.

18. The method of claim 17, wherein depositing the first portion of the second electrode comprises:
moving the substrate out of the first continuous aerosol jet emitted from the orifice after depositing the first portion of the first electrode;
moving the substrate relative to the orifice with the substrate out of the first continuous aerosol jet emitted from the orifice; and
moving the substrate into the first continuous aerosol jet emitted from the orifice to deposit the first portion of the second electrode.

19. The method of claim 17, wherein depositing the first portion of the second electrode comprises:
moving a masked portion of the substrate into the first continuous aerosol jet emitted from the orifice after depositing the first portion of the first electrode;
moving the substrate relative to the orifice with the masked portion of the substrate in the first continuous aerosol jet emitted from the orifice; and
moving an unmasked portion of the substrate into the first continuous aerosol jet emitted from the orifice to deposit the first portion of the second electrode.

20. The method of claim 17, further comprising:
flipping the substrate;
emitting a second continuous aerosol jet from the orifice;
depositing, from the second continuous aerosol jet emitted from the orifice, a second portion of the first electrode on a second major surface and the edge surface of the substrate, wherein the second major surface is opposite to the first major surface and the edge surface extends between the first major surface and the second major surface; and
depositing, from the second continuous aerosol jet emitted from the orifice, a second portion of the second electrode on the second major surface and the edge surface of the substrate.
